(19) United States
(12) Patent Application Publication
(10) Pub. No.: US 2025/0087633 A1
(43) Pub. Date: Mar. 13, 2025

(54) SEMICONDUCTOR PACKAGE AND METHOD FOR FORMING THE SAME

(71) Applicant: Taiwan Semiconductor Manufacturing Co., Ltd., Hsinchu (TW)

(72) Inventors: Yu-Chia Lai, Zhunan Township (TW); Ting Hao Kuo, Hsinchu (TW); Chen-Shien Chen, Zhubei City (TW); Chih-Sheng Li, Hsinchu (TW)

(21) Appl. No.: 18/520,414

(22) Filed: Nov. 27, 2023

Related U.S. Application Data
(60) Provisional application No. 63/581,024, filed on Sep. 7, 2023.

(51) Int. Cl. H01L 25/065; H01L 23/00; H01L 23/498; H01L 23/522; H01L 25/00

(52) U.S. Cl. CPC H01L 25/0652; H01L 23/49816; H01L 23/49822; H01L 23/49838; H01L 23/5226; H01L 24/08; H01L 24/32; H01L 24/94; H01L 25/50; H01L 2224/08146; H01L 2224/32145; H01L 2224/94; H01L 2924/181

(57) ABSTRACT

A device includes a package component including an interconnect structure on a first side of a substrate; metal pads on the interconnect structure; a semiconductor die connected to a second side of the substrate; a dielectric material surrounding the package component; a passivation layer extending over the package component and over the dielectric material; a first buffer layer over the passivation layer, wherein the first buffer layer extends over the package component and over the dielectric material, wherein a width of the first buffer layer is greater than a width of the package component and is less than a width of the passivation layer; and conductive connectors penetrating the passivation layer and the first buffer layer to physically contact the metal pads.

### PRIORITY CLAIM AND CROSS-REFERENCE

This application claims the benefit of U.S. Provisional Application No. 63/581,024, filed on Sep. 7, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is System on an Integrated Circuit (SoIC) technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package component, in accordance with some embodiments.

FIGS. 2, 3, 4, 5, 6, 7, 8, 9, 10, 11, 12, 13, and 14 illustrate cross-sectional views of intermediate stages in the formation of a package, in accordance with some embodiments.

FIG. 15 illustrates a cross-sectional view of a package, in accordance with some embodiments.

FIGS. 16, 17, and 18 illustrate cross-sectional views of packages having a buffer layer, in accordance with some embodiments.

FIGS. 19, 20, 21, 22, 23, 24, 25, 26, and 27 illustrate cross-sectional views of packages having multiple buffer layers, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package and a method of forming the same are provided. In accordance with some embodiments of the present disclosure, a semiconductor package comprises one or more package components and conductive connectors formed on a buffer layer over the one or more package components. The buffer layer may cover the package components and extend beyond the edges of the package components. By forming a buffer layer extending beyond the package components, stresses within the semiconductor package can be reduced. In some cases, the characteristics of the sidewalls of the buffer layer can be controlled to improve stress reduction. Additionally, multiple buffer layers can be formed to improve stress reduction. The techniques described herein may apply to a variety of packaging technologies, such as System on an Integrated Circuit (SoIC) technology or the like.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

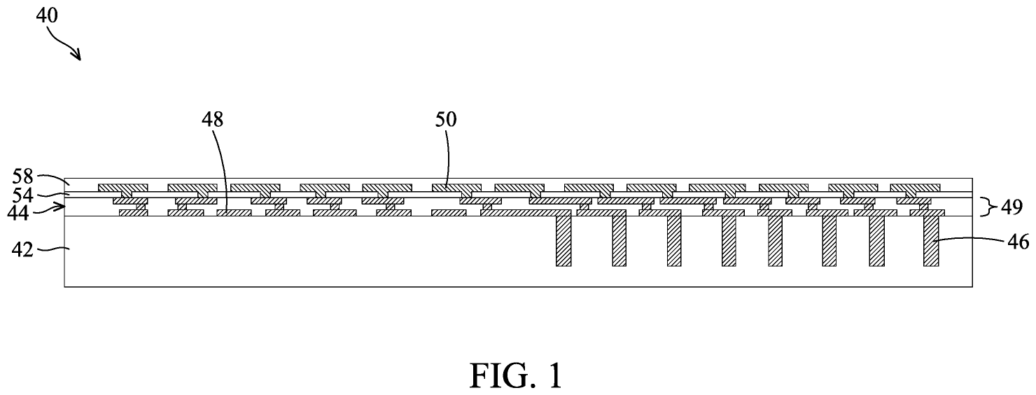

In FIG. 1, a first package component 40 is formed or provided, for example, in a wafer (not separately illustrated). In accordance with some embodiments, first package components 40 are individual device dies (e.g., integrated circuit dies), packages having one or more device dies packaged therein, System-on-Chip (SoC) dies including a plurality of integrated circuits integrated as a system, or the like. The device die(s) of first package components 40 may be or may comprise logic dies, memory dies, input-output (I/O) dies, Integrated Passive Devices (IPDs), the like, or combinations thereof. For example, the logic device die(s) of first package components 40 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of first package components 40 may include Static Random Access Memory (SRAM) dies, Dynamic Random Access Memory (DRAM) dies, or the like. The device die(s) of first package components 40 may include semiconductor substrates and interconnect structures.

In accordance with some embodiments, first package component 40 may include a substrate 42. The substrate 42 may be a semiconductor substrate, such as a bulk semiconductor, a semiconductor-on-insulator (SOI) substrate, or the like, which may be doped (e.g., with a p-type or an n-type dopant) or undoped. The substrate 42 may be a wafer, such as a silicon wafer. Other substrates, such as a silicon-on-insulator (SOI) substrate, a multi-layered substrate, or a gradient substrate may also be used. In some embodiments, the semiconductor material of the substrate 42 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, multiple first package components 40 may be formed on the same substrate 42 and then separated into individual first package components 40 using a singulation process (e.g., a sawing process, dicing process, or the like).

Further, integrated circuit devices (not separately illustrated) may be formed at a front-side surface of the substrate 42, in some embodiments. The integrated circuit devices may include active devices (e.g., NMOS and PMOS transistors, diodes, etc.), passive devices (e.g., resistors, capacitors, etc.), and the like. In addition, through-substrate vias (TSVs) 46 may be formed extending partially through the substrate 42.

In some embodiments, an interconnect structure 49 is formed over the front-side of the substrate 42. The interconnect structure 49 includes conductive features 48 (e.g., metal lines, metal vias, metal pads, etc.) formed in one or more dielectric layers 44. Conductive features 48 of the interconnect structure 49 may be electrically connected to the integrated circuit devices and/or the TSVs 46. As illustrated, the interconnect structure 49 may include multiple layers of conductive features 48 formed in multiple dielectric layers 44. The conductive features 48 may be formed using a damascene process, a dual damascene process, or another suitable technique. The conductive features 48 may comprise, for example, copper, aluminum, tungsten ruthenium, cobalt, alloys thereof, combinations thereof, or the like. The dielectric layers 44 may be formed of or comprise a dielectric material such as polymer, silicon nitride, silicon oxide, silicon oxynitride, silicon oxycarbide, silicon carbonitride, the like, combinations thereof, and/or multi-layers thereof. Other materials are possible. In some cases, the dielectric layers 44 may be Inter-Metal Dielectric (IMD) layers. The interconnect structure 49 shown in FIG. 1 is an example, and an interconnect structure 49 may comprise another number of layers or may have a different configuration than shown. In some embodiments, the interconnect structure 49 may comprise a seal ring (not shown).

A passivation layer 54 may be formed over the interconnect structure 49, in accordance with some embodiments. The passivation layer 54 may be formed of a non-low-k dielectric material having a dielectric constant equal to or greater than the dielectric constant of silicon oxide, in some embodiments. The passivation layer 54 may be formed of or comprise an inorganic dielectric material, which may include a material selected from, but not limited to, silicon nitride, silicon oxide, silicon oxynitride, silicon oxycarbide, silicon carbonitride, the like, combinations thereof, and/or multi-layers thereof. Other materials are possible.

Metal pads 50 may be formed on the passivation layer 54, in accordance with some embodiments. The metal pads 50 are formed on the passivation layer 54 and may have portions extending through the passivation layer 54 to physically and electrically contact conductive features 48 of the interconnect structure 49. The metal pads 50 can help facilitate external electrical connection to the integrated circuit of first package components 40 during functional use and/or facilitate external electrical connection during, for example, wafer acceptance testing (e.g., circuit probe testing) of the first package components 40. Some of the metal pads 50 may be connected to TSVs 46 by interconnect structure 49. Some of the metal pads 50 may be connected to the integrated circuit devices at the surface of the substrate 42 by interconnect structure 49.

As an example of forming the metal pads 50, the passivation layer 54 may be patterned using photolithographic and etching techniques to expose the interconnect structure 49. The patterned passivation layer 54 exposes top-most conductive features 48 of the interconnect structure 49. A seed layer (not shown) may be deposited over the passivation layer 54 and on the exposed conductive features 48. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, sputtering, evaporation, Physical Vapor Deposition (PVD), Chemical Vapor Deposition (CVD), Plasma Enhanced Chemical Vapor Deposition (PECVD), or the like. A photoresist (not shown) is then formed and patterned on the seed layer. The photoresist may be formed by spin coating or the like and may be exposed to light for patterning. The pattern of the photoresist corresponds to the metal pads 50. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal such as aluminum copper, copper, aluminum, nickel, tungsten, the like, or alloys thereof. Other conductive materials are possible. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed using an acceptable etching process, such as a wet etching process or dry etching process. The remaining portions of the seed layer and conductive material form the metal pads 50.

In some embodiments, a dielectric layer 58 may be deposited over the passivation layer 54 and the metal pads 50. The dielectric layer 58 may protect the metal pads 50, for example, from oxidization. In some embodiments, the dielectric layer 58 is an anti-reflective coating (ARC) and comprises an oxide or a nitride, such as silicon oxide (SiO), silicon nitride (SiN), silicon oxynitride (SiON), or any suitable material. In other embodiments, the dielectric layer 58 may include one or more materials such as Phospho-Silicate Glass (PSG), Boro-Silicate Glass (BSG), Boron-Doped Phospho-Silicate Glass (BPSG), undoped Silicate Glass (USG), low-k dielectric materials, or the like. The dielectric layer 58 may be formed using a suitable process such as spin coating, Flowable Chemical Vapor Deposition (FCVD), PECVD, Low Pressure Chemical Vapor Deposition (LPCVD), or the like. Other materials or deposition techniques are possible. In some embodiments, an optional planarization process (e.g., Chemical Mechanical Polish (CMP), grinding, or the like) is performed on the dielectric layer 58 such that the top surface of the dielectric layer 58 is approximately planar.

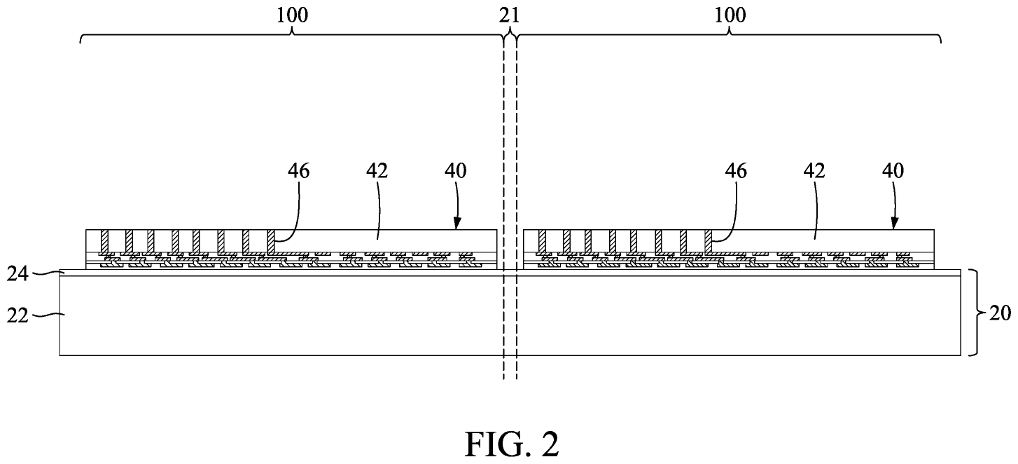

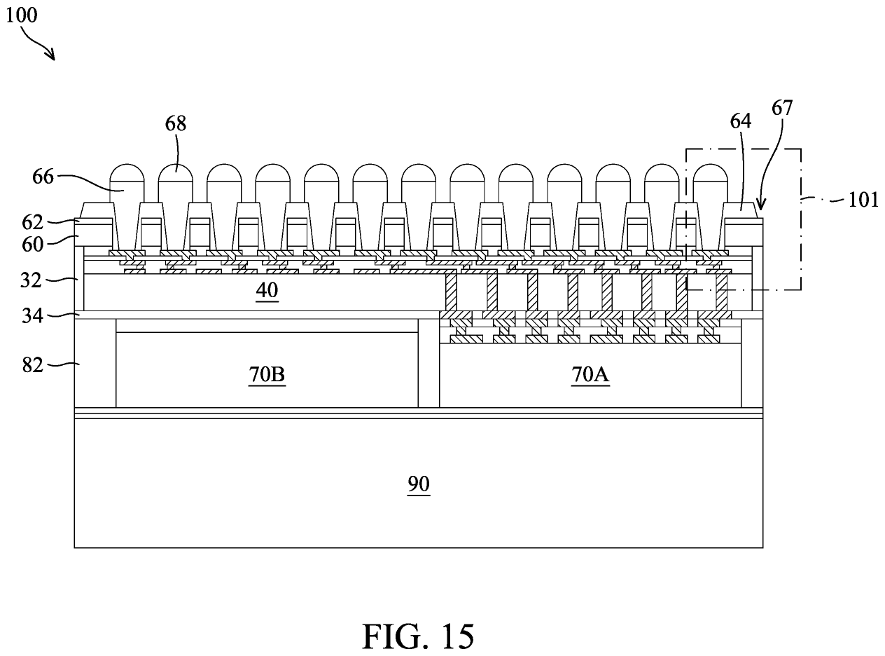

In FIG. 2, one or more first package components 40 are attached to a first carrier 20, in accordance with some embodiments. Packages 100 are subsequently formed on the first carrier 20, indicated in FIG. 2 by package regions 100. Each package region 100 is separated from a neighboring package region 100 by a scribe region 21. The structure is subsequently singulated along scribe regions 21 to form separate, individual packages 100 (see FIG. 15). FIG. 2 illustrates a single first package component 40 in each package region 100, but in other embodiments, a package region 100 may comprise more than one first package component 40 and/or other package components.

The first carrier 20 may include a base carrier 22 and one or more dielectric bond layers 24. In some embodiments, the base carrier 22 may be a wafer and may be a similar material as the substrate 42 of the first package component 40. In this manner, during process, warpage caused by a mismatch of Coefficients of Thermal Expansion (CTE) between the first carrier 20 and the first package component 40 may be reduced. For example, in some embodiments, the base carrier 22 may be formed of or comprise silicon. Other embodiments may use other materials such as laminate, ceramic, glass, silicate glass, organic core, the like, or a combination thereof. In accordance with some embodiments, the entire base carrier 22 is formed of a homogeneous material, with no other material different from the homogeneous material therein. In some embodiments, the entire base carrier 22 may be formed of silicon (doped or undoped), and without a metal region, dielectric region, etc., therein.

Before attaching first package components 40 to the first carrier 20, a dielectric bond layer 24 may be deposited on the base carrier 22. The dielectric bond layer 24 may include one layer or multiple layers comprising one or more materials such as oxide-based materials such as silicon oxide (SiO), PSG, BSG, BPSG, fluorine-doped silicate glass (FSG), or the like; nitride-based materials such as silicon nitride (SiN) or the like; oxynitride based materials such as silicon oxynitride (SiON) or the like; or other materials such as silicon oxycarbide (SiOC), silicon carbonitride (SiCN), or the like. Dielectric bond layers 24 may be formed using spin coating, FCVD, PECVD, LPCVD, Atomic Layer Deposition (ALD), the like, or combinations thereof. For example, in some embodiments, the dielectric bond layers 24 may include a lowermost layer (e.g., proximal to base carrier 22) comprising an oxide, one or more middle layers comprising a nitride and/or an oxynitride, and an uppermost layer (e.g., distal from base carrier 22) comprising an oxynitride (e.g., with a lower nitrogen-to-oxygen ratio as compared with the middle layers). Although not separately illustrated, alignment marks may be formed in the dielectric bonding layers 24 (e.g., the uppermost layer) using any suitable method.

In some embodiments, the first package components 40 are attached to the first carrier 20 using a direct bonding process, such as fusion bonding or dielectric-to-dielectric bonding. In accordance with some embodiments, the bonding of the first package components 40 to the first carrier 20 includes pre-treating the dielectric bond layers 24 and/or the dielectric layers 58 with a process gas comprising oxygen (O₂) and/or nitrogen (N₂), performing a pre-bonding process to bond dielectric bond layers 24 and dielectric layers 58 together, and performing an annealing process following the pre-bonding process to strengthen the bond.

In accordance with some embodiments, during the pre-bonding process, the first package components 40 are put into physical contact with the first carrier 20, with a pressing force applied to press the first package components 40 against the first carrier 20. The pre-bonding process may be performed at room temperature (e.g., in a range from about 20° C. to about 25° C.), though a higher temperature may also be used. After the pre-bonding process, an annealing process is performed to bond the dielectric bond layers 24 and dielectric layers 58 together. In accordance with some embodiments, the annealing process is performed at a temperature in a range from 200° C. to 350° C. The annealing duration may be in a range from 30 minutes to 60 minutes.

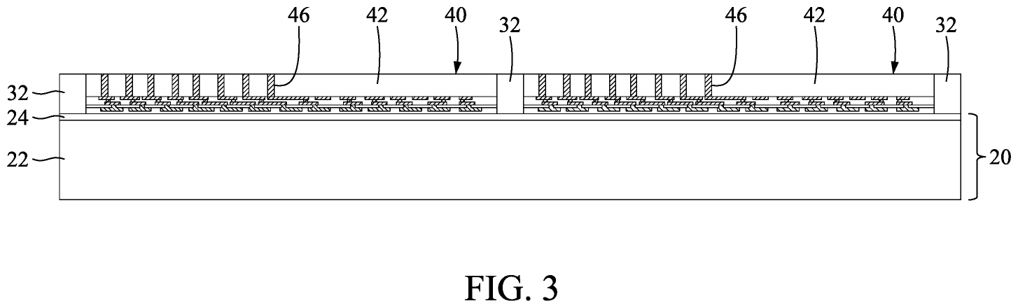

In FIG. 3, a gap-filling material 32 is deposited over the first package components 40 and the first carrier 20, in accordance with some embodiments. The gap-filling material 32 may encapsulate, protect, and/or insulate the first package components 40. In some embodiments, the gap-filling material 32 may include an optional liner layer and a bulk layer (not separately illustrated). For example, the liner layer may be a conformal layer extending along the top surfaces and the sidewalls of the first package components 40 and along top surfaces of the dielectric bond layer 24. The liner layer may also be referred to as a seal-ring and, in some embodiments, is used as an etch stop layer in subsequent steps. The liner layer may be formed of a dielectric material such as silicon nitride, silicon oxide, the like, or a combination thereof. The liner layer may be deposited using a suitable conformal deposition process such as ALD, CVD, or the like. The bulk layer of the gap-filling material 32 may be formed of a molding compound, an epoxy, a resin, a nitride such as silicon nitride, an oxide such as silicon oxide, an insulating material, the like, or a combination thereof. The bulk layer may be deposited using a suitable process, such as compression molding, spin coating, FCVD, PECVD, LPCVD, ALD, or the like.

In some embodiments, a planarization process such as a CMP process and/or a grinding process is then performed to remove portions of the gap-filling material 32. The planarization process may remove gap-filling material 32 such that the first package components 40 are exposed, as shown in FIG. 3. Further, the planarization process may remove portions of the substrates 42 of the first package components 40 such that the TSVs 46 of the first package components 40 are exposed, as shown in FIG. 3. After performing the planarization process, surfaces of the gap-filling material 32, substrates 42, and/or TSVs 46 may be level or coplanar (within process variations).

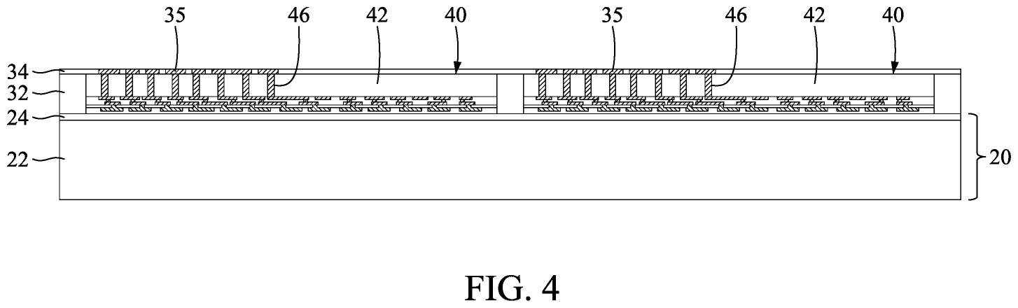

In FIG. 4, a dielectric bond layer 34 and bond pads 35 are formed over the back-side surface of first package component 40 (e.g., the upper surface of substrate 42 as illustrated). In some embodiments, the dielectric bond layer 34 is first deposited over the first package components 40 and the gap-filling material 32 using any suitable method such as ALD, CVD, or the like. The dielectric bond layer 34 is patterned using suitable photolithography and etching techniques to form openings (not separately illustrated) that may expose surfaces of the TSVs 46 and/or the substrates 42. The openings are then filled with a conductive material to form bond pads 35, in accordance with some embodiments. The conductive material may be similar to those described previously for the metal pads 50 and may be formed using similar techniques. In this manner, the bond pads 35 may physically and electrically contact the TSVs 46. In some embodiments, a planarization process (e.g., CMP or grinding) is performed such that surfaces of the dielectric bond layer 34 and bond pads 35 may be approximately level or coplanar.

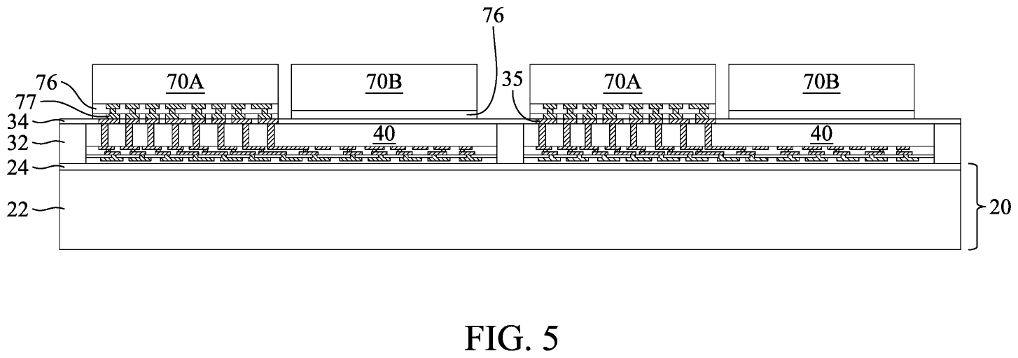

In FIG. 5, second package components 70 are attached to the first package components 40, in accordance with some embodiments. The second package components 70 may include, for example, active package components 70A and dummy package components 70B. The active package components 70A may include functional components such as integrated circuits or the like. The dummy package components 70B may be included, for example, to provide structural integrity and/or heat dissipation.

In some embodiments, the active package components 70A and/or the dummy package components 70B may be attached using a direct bonding process, such as a dielectric-to-dielectric bonding process and/or a metal-to-metal bonding process (e.g., a fusion bonding process, a hybrid bonding process, or the like). Although FIG. 5 illustrates the attachment of one active package component 70A and one dummy package component 70B to each first package component 40, in other embodiments any suitable number or types of second package components 70 may be attached to each first package component 40. For example, in other embodiments, no dummy package components 70B may be attached or multiple active package components 70A of various types may be attached.

In some embodiments, the active package components 70A may be individual device dies (e.g., integrated circuit dies), packages having one or more device dies packaged therein, System-on-Chip (SoC) dies including a plurality of integrated circuits (or device dies) integrated as a system, or the like. The device die(s) of the active package components 70A may comprise logic dies, memory dies, input-output (I/O) dies, Integrated Passive Devices (IPDs), the like, or combinations thereof. For example, the logic device die(s) of the active package components 70A may comprise Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of active package components 70A may include Static Random Access Memory (SRAM) dies, Dynamic Random Access Memory (DRAM) dies, or the like. The device die(s) of the active package components 70A may include semiconductor substrates and interconnect structures. In accordance with some embodiments, first package components 40 are SoC dies, and active package components 70A comprise memory dies, such as SRAM dies.

In accordance with some embodiments (not separately illustrated), active package components 70A may include some features similar to those described above for first package components 40. For example, the active package components 70A may comprise a semiconductor substrate, integrated circuit devices, and a plurality of dielectric layers formed over the semiconductor substrate and the integrated circuit devices. The integrated circuit devices may include active devices, passive devices, or the like. In accordance with some embodiments, the dummy package components 70B do not include functional integrated circuits and/or are electrically disconnected from the first package components 40 and/or the second active components 70A. The second package components 70 may each comprise a dielectric bond layer 76 that is subsequently bonded to the dielectric bond layer 34. The active package components 70A may further include bond pads 77 formed within the dielectric bond layer 76. In some embodiments, the dummy package components 70B may also comprise dummy bond pads (not illustrated).

In accordance with some embodiments, the dielectric bond layers 76 are directly bonded to the dielectric bond layer 34 using dielectric-to-dielectric bonding. Similarly, the bond pads 77 are directly bonded to bond pads 35 using metal-to-metal bonding. The bonding may include a pre-bonding process and an annealing process, in some embodiments. During the pre-bonding process, a small pressing force may be applied to press second package components 70 against the first package components 40. The pre-bonding process may be performed at a low temperature, such as room temperature (e.g., a temperature in the range from about 20° C. to about 25° C.). After the pre-bonding process, the dielectric bond layers 76 and the dielectric bond layer 34 are bonded to each other. The bonding strength may then be improved in a subsequent annealing step, in which the dielectric bond layers 76 and dielectric bond layer 34 are annealed at a high temperature, such as a temperature in the range from about 200° C. to about 350° C. In this manner, the dielectric bond layers 76 and the dielectric bond layer 34 are bonded to each other by dielectric-to-dielectric bonding. Additionally, the annealing step bonds the bond pads 77 of the second package components 70 (e.g., the active package components 70A) to the bond pads 35 by metal-to-metal bonding.

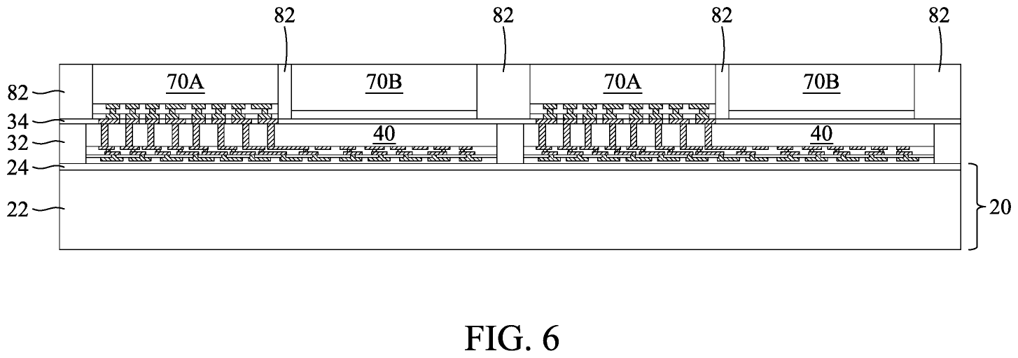

In FIG. 6, a gap-filling material 82 is deposited over the second package components 70 and the dielectric bond layer 34, in accordance with some embodiments. The gap-filling material 82 may encapsulate the second package components 70. The gap-filling material 82 may be similar to the gap-filling material 32 described previously for FIG. 3, and may be formed using similar techniques. For example, the gap-filling material 82 may include an optional liner layer and a bulk layer (not separately illustrated). In some cases, the gap-filling material 82 comprises different materials than the gap-filling material 32. In some embodiments, a planarization process (e.g., CMP, grinding, or the like) is performed to remove portions of the gap-filling material 82. The planarization process may remove gap-filling material 82 such that the second package components 70 are exposed, as shown in FIG. 3. After performing the planarization process, surfaces of the gap-filling material 82 and the second package components 70 may be level or coplanar (within process variations).

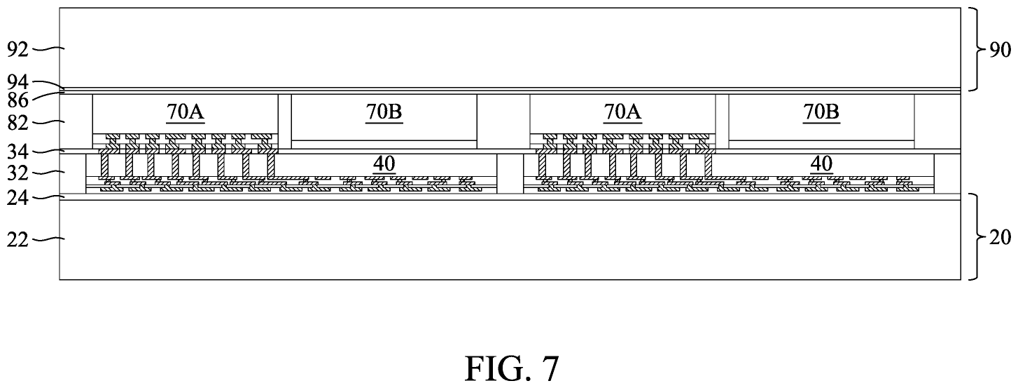

In FIG. 7, a second carrier 90 is attached, in accordance with some embodiments. The second carrier 90 may include a base carrier 92 and one or more dielectric bond layers 94. In some embodiments, the base carrier 92 and the dielectric bond layers 94 may be similar to the base carrier 22 and the dielectric bond layers 24 of the first carrier 20 described previously. For example, the base carrier 92 may be a similar material as the base carrier 22 to reduce warpage caused by CTE mismatch. Before attaching the second carrier 90, one or more dielectric bond layers 94 are deposited on the base carrier 92 and one or more dielectric bond layers 86 are deposited over the second package components 70 and the gap-filling material 82. The second carrier 90 may be attached using dielectric-to-dielectric bonding. For example, in accordance with some embodiments, the bonding of second carrier includes pre-treating dielectric bond layers 86 and 94 in a process gas comprising oxygen (O₂) and/or nitrogen (N₂), performing a pre-bonding process to bond dielectric bond layers 86 and 94 together, and performing an annealing process following the pre-bonding process to strengthen the bond.

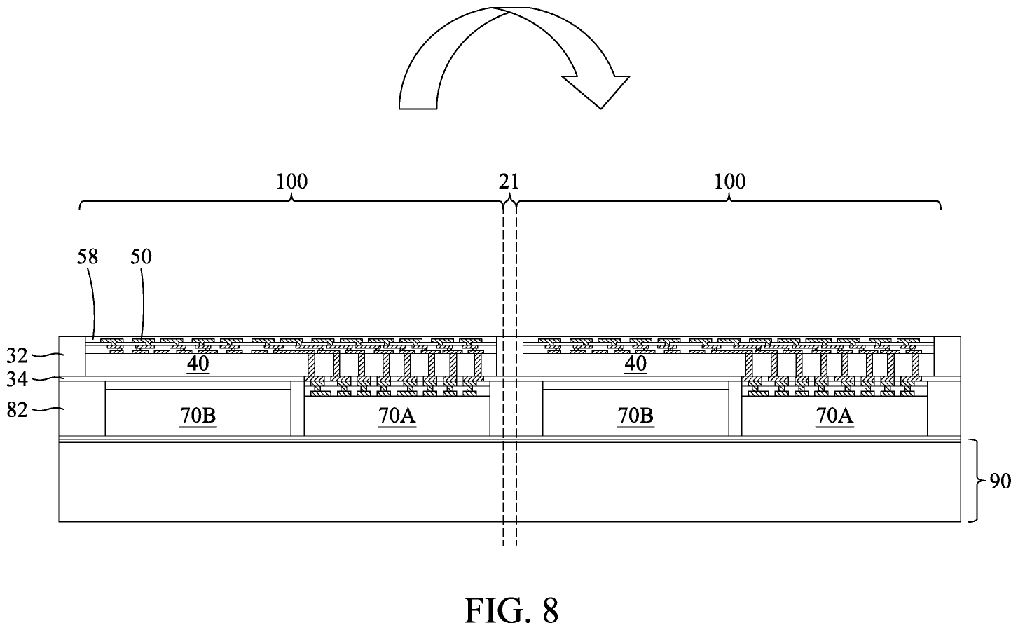

In FIG. 8, the structure is flipped over and the first carrier 20 is removed, in accordance with some embodiments. The first carrier 20 may be removed using any suitable method, such as using a planarization process and/or an etching process. The planarization process may be a CMP process, a grinding process, the like, or a combination thereof. The etching process may be a wet etching process, a dry etching process, or a combination thereof. As shown in FIG. 8, removing the first carrier 20 exposes the dielectric layer 58 and the gap-filling material 32. In some embodiments, after removing the first carrier 20, surfaces of the dielectric layer 58 and the gap-filling material 32 are level or coplanar (within process variations).

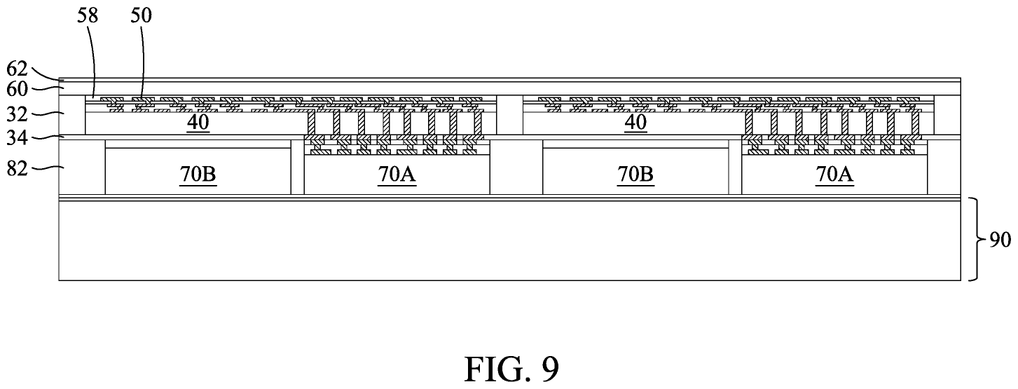

In FIG. 9, a first passivation layer 60 and a second passivation layer 62 are deposited, in accordance with some embodiments. In some embodiments, the first passivation layer 60 comprises a dielectric material such as silicon oxide (SiO), PSG, BSG, BPSG, FSG, USG, silicon oxynitride (SiON), silicon oxycarbide (SiOC), or the like. In some embodiments, the second passivation layer 62 comprises a dielectric material different from that of the first passivation layer 60, such as silicon nitride (SiN), silicon oxynitride (SiON), silicon carbonitride (SiCN), or the like. For example, in some embodiments, the first passivation layer 60 is USG and the second passivation layer 62 is silicon nitride, though other materials are possible. The first passivation layer 60 and the second passivation layer 62 may be deposited using suitable techniques such as spin coating, FCVD, CVD, PECVD, or the like. In some embodiments, an optional planarization process (e.g., CMP, grinding, or the like) is performed on the second passivation layer 62 such that the top surface of the second passivation layer 62 is approximately planar.

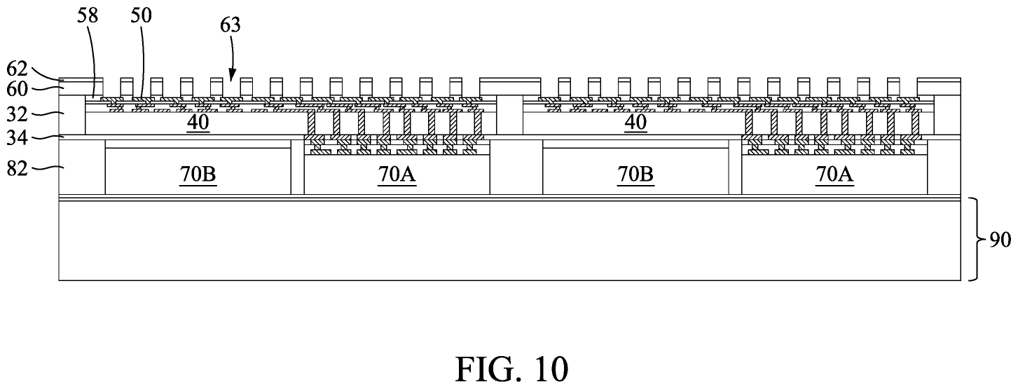

In FIG. 10, openings 63 are formed in the first passivation layer 60, the second passivation layer 62, and the dielectric layer 58 to expose metal pads 50, in accordance with some embodiments. The openings 63 may be formed using suitable photolithography and etching techniques. For example, a photoresist may be applied over a top surface of the second passivation layer 62 and patterned. The patterned photoresist is then used as an etching mask to etch portions of the first passivation layer 60, the second passivation layer 62, and the dielectric layer 58, forming the openings 63. The etching may include one or more dry etching processes and/or wet etching processes. As stated above, surfaces of the metal pads 50 are exposed by the openings 63.

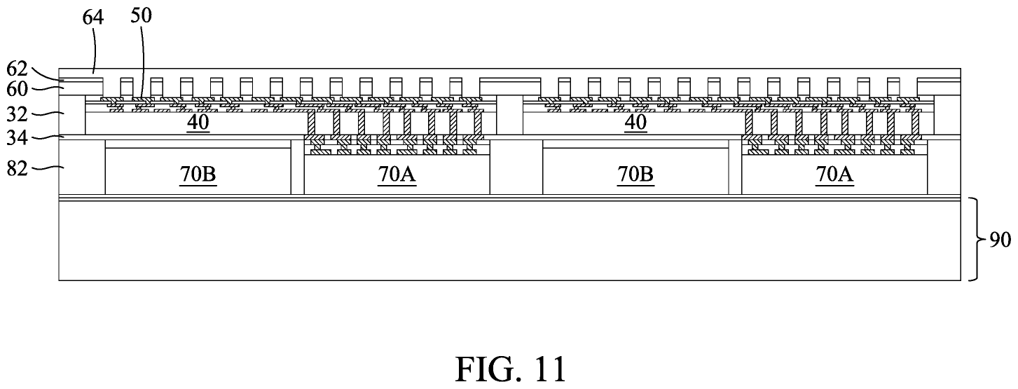

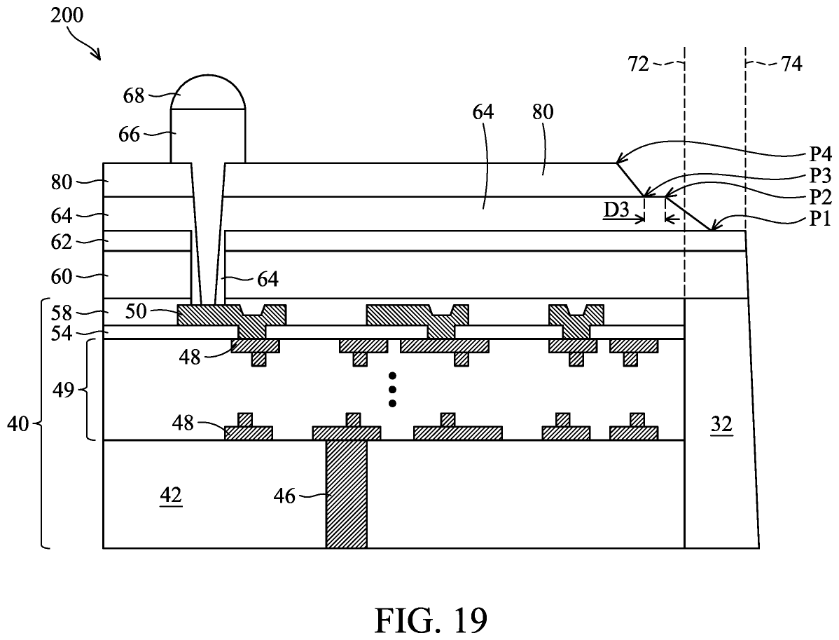

In FIG. 11, a buffer layer 64 is deposited over the structure and within the openings 63, in accordance with some embodiments. For example, the buffer layer 64 may fill the openings 63 and may cover top surfaces of the second passivation layer 62. The buffer layer 64 may comprise a polymer material, such as polyimide, polybenzoxazole (PBO), benzocyclobutene (BCB), an epoxy, or the like. The polymer may be photo-sensitive or non-photo-sensitive. The buffer layer 64 may be deposited using a suitable process, such as spin coating, lamination, or the like. In some cases, a curing process (e.g., a thermal treatment) may be performed on the buffer layer 64. In some embodiments, the buffer layer 64 may be deposited to a thickness on the second passivation layer 62 that is in the range of about 3 μm to about 10 μm. Other materials or thicknesses thereof are possible. In other embodiments, a second buffer layer is formed over the buffer layer 64, and some example embodiments are described below for FIGS. 19-27.

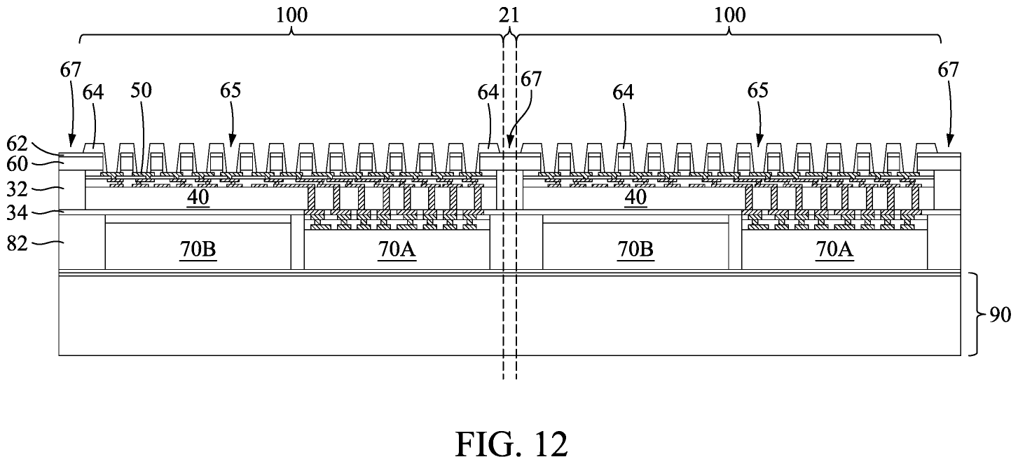

In FIG. 12, the buffer layer 64 is patterned, in accordance with some embodiments. The buffer layer 64 is patterned to form openings 65 that expose metal pads 50. After forming the openings 65, portions of the buffer layer 64 may remain on sidewalls of the first passivation layer 60 and the second passivation layer 62 (e.g., on sidewalls of the openings 63). Portions of the buffer layer 64 may also remain on top surfaces of the metal pads 50.

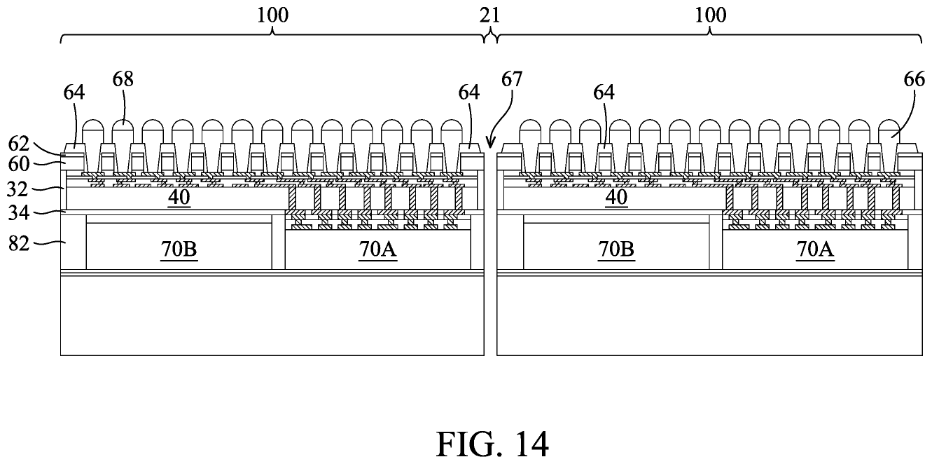

The buffer layer 64 is also patterned to form openings 67 near the edges of the package regions 100 that expose the second passivation layer 62. In some embodiments, the openings 67 overlap the scribe regions 21, such that forming the openings 67 comprises removing the buffer layer 64 from the scribe regions 21. By removing the buffer layer 64 from the scribe regions 21, the material of the buffer layer 64 does not interfere with the subsequently performed singulation process (see FIG. 14). In this manner, the singulation process may be improved. Further, in some embodiments, the locations and/or profiles of the sidewalls of the openings 67 may be controlled to reduce stress within the package 100, described in greater detail below. For example, in some cases, having the buffer layer 64 laterally protrude beyond the first package component 40 can reduce stress due to CTE mismatch and reduce delamination.

The patterning of the buffer layer 64, when it is photo-sensitive, may include performing a photo-exposure process on the buffer layer 64, such as exposing the buffer layer 64 to light corresponding to the subsequently performed pattern. The buffer layer 64 may then be developed using appropriate techniques to form the openings 65 and 67. In some embodiments, the characteristics of the openings 65 and 67, such as the sidewall slope, may be controlled by controlling the parameters of the light exposure. In accordance with alternative embodiments in which the buffer layer 64 is not photo-sensitive, the patterning of the buffer layer 64 may include, for example, applying and patterning a photoresist over the buffer layer 64, and etching the buffer layer 64 using the patterned photoresist as an etching mask.

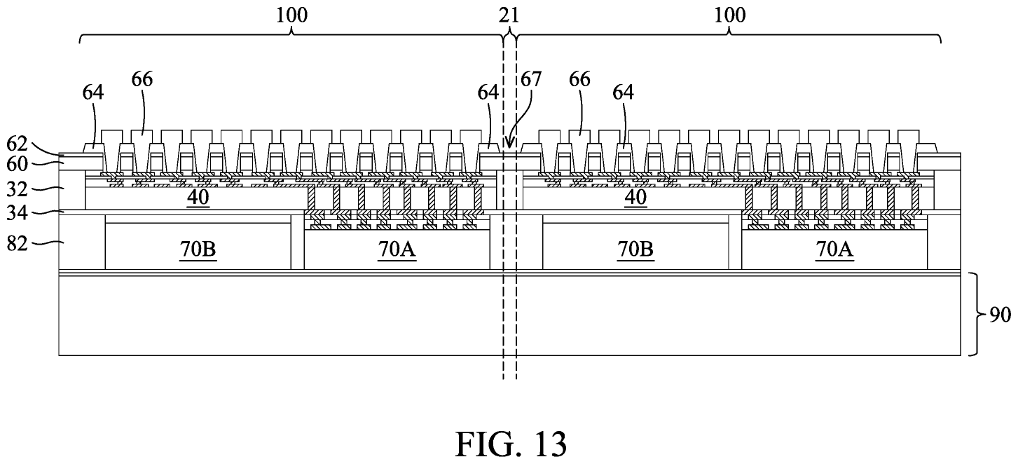

In FIG. 13, under-bump metallizations (UBMs) 66 are formed in the openings 65, in accordance with some embodiments. In some embodiments, the UBMs 66 are not formed in the openings 67, as shown in FIG. 13. The UBMs 66 are formed in the openings 65 and are electrically connected to the metal pads 50. As an example to form the UBMs 66, a seed layer (not separately illustrated) is formed over the exposed surfaces of the metal pads 50 and the buffer layer 64. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 66. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 66. In other embodiments, the UBMs 66 may include a liner layer, such as an adhesion layer. In other embodiments, the UBMs 66 may have top surfaces that are level with top surfaces of the buffer layer 64.

In FIG. 14, conductive connectors 68 are formed on the UBMs 66, and the packages 100 are singulated into individual packages 100, in accordance with some embodiments. Conductive connectors 68 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. Conductive connectors 68 may include a conductive material such as solder, copper, aluminum, gold, nickel, silver, palladium, tin, the like, or a combination thereof. In some embodiments, conductive connectors 68 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, conductive connectors 68 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, some or all of the UBMs 66 are formed as part of the conductive connectors 68.

After forming the conductive connectors 68, a singulation process is performed along scribe regions 21, separating neighboring package regions 100, in accordance with some embodiments. In this manner, individual packages 100 are formed. FIG. 15 illustrates a singulated package 100, in accordance with some embodiments. The singulation process may include a sawing process, a dicing process, an etching process, or the like. As shown in FIG. 14, after performing the singulation process, sidewalls of a buffer layer 64 are laterally recessed from sidewalls of the respective package 100. In some embodiments, the sidewalls of the packages 100 may be approximately coplanar, and may be vertical or have a nonzero angle from vertical. For example, the sidewalls of the second passivation layer 62, the first passivation layer 60, the gap-filling material 32, the dielectric bond layer 34, the gap-filling material 82, and/or the second carrier 90 may have approximately coplanar surfaces (e.g., within process variations).

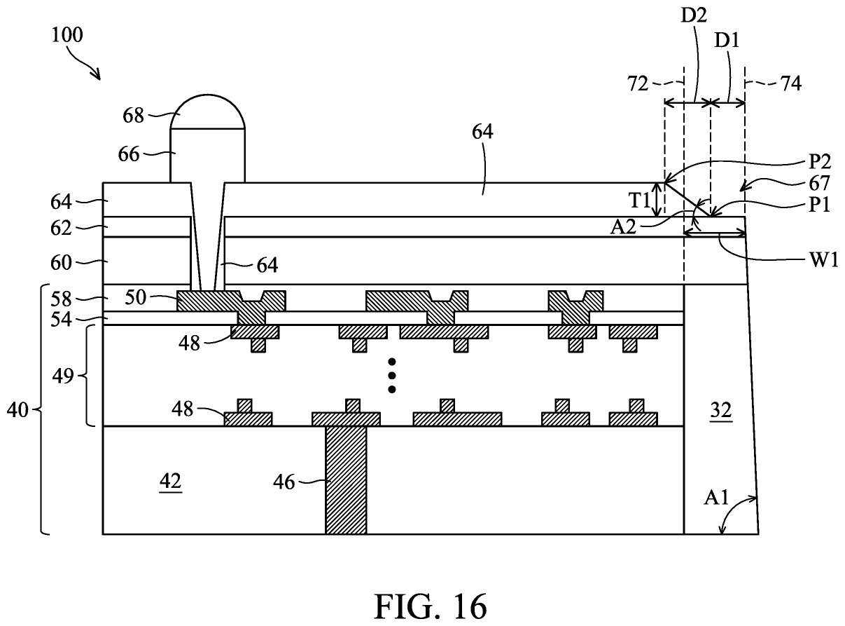

FIGS. 16, 17, and 18 illustrate magnified views of portions of packages 100, in accordance with some embodiments. The packages 100 shown in FIGS. 16-18 may be similar to the package 100 shown in FIG. 15 and may be formed using similar techniques. The magnified views of FIGS. 16-18 show the buffer layer 64 near a sidewall of the package 100, and may show a region similar to the region 101 indicated in FIG. 15. The embodiments shown in FIGS. 16-18 are intended as non-limiting examples, and a package 100 and/or a buffer layer 64 may be formed having different characteristics than shown using the techniques described herein. As described previously, in some embodiments, the buffer layer 64 is formed extending beyond a sidewall of the first package component 40. For example, the buffer layer 64 may be formed such that a distance between opposite sides of the buffer layer 64 (e.g., the total lateral width of the buffer layer 64 as shown in FIG. 15) is greater than a distance between opposite sides of the first package component 40 (e.g., the total lateral width of the first package component 40 as shown in FIG. 15) and is less than a distance between opposite sides of the package 100 (e.g., the total lateral width of the package 100 shown in FIG. 15). In some embodiments, a width of the buffer layer 64 may be greater than a width of the first package component 40 and less than a width of the second passivation layer 62. In some embodiments, the buffer layer 64 may partially overlap (e.g., extend over a portion of) the gap-filling material 32.

In some cases, forming the buffer layer 64 such that it protrudes beyond the edges of the first package component 40, as described herein, can reduce stress within a package 100. For example, stress or warping due to CTE mismatch between the buffer layer 64 and the first package component 40 can be reduced using the techniques described herein. In some cases, stresses within a package due to CTE mismatch can be reduced as much as 10% using the techniques described herein, but other results are possible. In this manner, the thermal performance of a package may be improved. Further, undesirable effects such as warping, peeling, delamination, or the like can be reduced, which can improve device yield and reliability. Accordingly, FIGS. 16-18 illustrate non-limiting examples of embodiments in which stress within the package 100 may be reduced by forming the buffer layer 64 to extend beyond a sidewall of the first package component 40.

Referring to FIG. 16, a portion of a package 100 is shown, in accordance with some embodiments. As mentioned above, the package 100 of FIG. 16 may be similar to the package 100 shown in FIG. 15 and may be formed using similar techniques. For example, the buffer layer 64 may be deposited over the second passivation layer 62 and then patterned to form openings 67 over scribe regions 21 (see FIG. 13). The scribe regions 21 are then removed during a singulation process, which forms the sidewalls of the package 100. In some embodiments, the sidewalls of the package 100 may have an angle A1 that is in the range of about 75° to about 90°, though other angles are possible.

In FIG. 16, a vertical edge of the sidewall of the first package component 40 is indicated as component edge 72, and a vertical edge of the upper sidewall of the package 100 is indicated as package edge 74. The package edge 74 may correspond to the upper sidewall of a layer underlying the buffer layer 64, such as the upper sidewall of the second passivation layer 62. In some embodiments, a lateral width W1 between the component edge 72 and the package edge 74 is in the range of about 20 μm to about 40 μm, though other widths are possible.

As shown in FIG. 16, the buffer layer 64 may have a thickness Ti that is in the range of about 3 μm to about 10 μm, though other thicknesses are possible. In some embodiments, the sidewall of the buffer layer 64 may have an angle A2 that is in the range of about 60° to about 90°, though other angles are possible. The bottom edge of the buffer layer 64 sidewall is indicated as point P1, and the top edge of the buffer layer 64 sidewall is indicated as point P2. In some embodiments, a lateral distance D2 between point P1 and point P2 is in the range of about 5 μm to about 20 μm, though other distances are possible.

In the embodiment shown in FIG. 16, the point P1 is laterally between the component edge 72 and the package edge 74, and the point P2 is opposite the component edge 72 from the point P1. In other words, the point P1 is over the gap-filling material 32 and the point P1 is over the first package component 40. By having the sidewall of the buffer layer 64 extend over the component edge 72, stress in the package 100 can be reduced, in some cases. In some embodiments, the point P1 is a lateral distance D1 from the package edge 74 that is in the range of about 0.1 μm to about 5 μm. In some embodiments, the distance D1 is between about 1% and about 70% of the width W1. Other distances are possible.

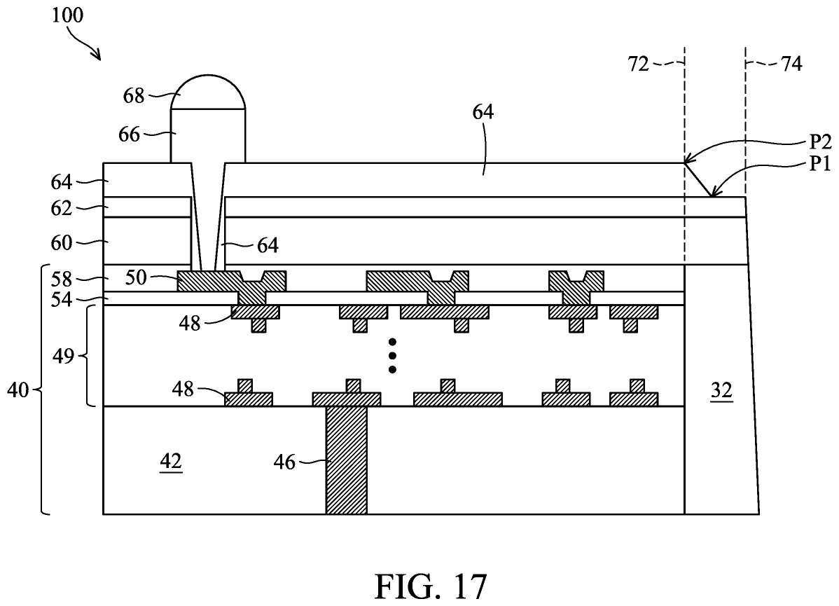

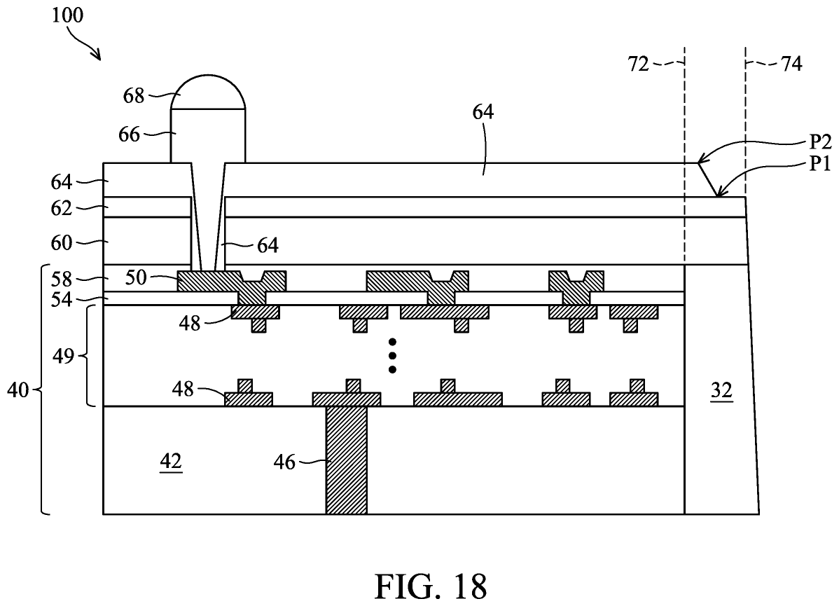

The characteristics of the sidewall of the buffer layer 64 may be controlled to appropriately reduce stress in a package according to the composition and configuration of the package. For example, the sidewall angle A2 (e.g., the sidewall slope), the distances D1 and D2, and/or the locations of the points P1 and P2 may be controlled to provide reduced stress for a particular package design. FIGS. 17 and 18 illustrate other buffer layers 64 having other sidewall characteristics, in accordance with some embodiments. The characteristics of the sidewall of the buffer layer 64 may be controlled by controlling the formation of the opening 67 (see FIG. 16), in some embodiments. For example, the sidewall characteristics may be controlled by controlling the pattern, energy, and/or focus of the light exposure process, when the buffer layer 64 is photo-sensitive. The sidewall characteristics may also be controlled by controlling the temperature or duration of the curing process, or controlling parameters of the development process, in some cases.

FIG. 17 illustrates a package 100 similar to that shown in FIG. 16, except that the point P2 of the buffer layer 64 is approximately aligned with the component edge 72. As shown in FIG. 17, the point P1 of the buffer layer 64 is between the component edge 72 and the package edge 74. FIG. 18 illustrates a package 100 similar to that shown in FIG. 16, except that the point P2 of the buffer layer 64 is approximately aligned with the component edge 72. As shown in FIG. 17, the point P1 of the buffer layer 64 is between the component edge 72 and the package edge 74. FIG. 18 illustrates an embodiment similar to that shown in FIG. 16, except that the point P2 of the buffer layer 64 is over the gap-filling material 32. In other words, both points P1 and P2 are between the component edge 72 and the package edge 74.

FIGS. 19 through 27 illustrate magnified views of portions of packages 200, in accordance with some embodiments. The packages 200 shown in FIGS. 19-27 may be similar to the packages 100 described for FIGS. 15-18, except that a second buffer layer 80 is formed over the buffer layer 64. In some cases, forming a second buffer layer 80 can further reduce stress within the package 200 and thus improve yield, reliability, and/or thermal performance. The characteristics of both the buffer layer 64 and the second buffer layer 80 may be controlled independently to reduce stress according to the particular structure of a package 200. The magnified views of FIGS. 19-27 show a region similar to the region 101 indicated in FIG. 15. The embodiments shown in FIGS. 19-27 are intended as non-limiting examples, and a package 200, a buffer layer 64, and/or a buffer layer 80 may be formed having different characteristics than shown using the techniques described herein.

The second buffer layer 80 may be a material that is similar or different than the material of the underlying buffer layer 64. The second buffer layer 80 may be a material such as those described previously for the buffer layer 64 and may be formed using similar techniques. For example, in some embodiments, the second buffer layer 80 may be a photo-sensitive polymer material, such as polyimide, polybenzoxazole (PBO), benzocyclobutene (BCB), or the like. In some embodiments, the second buffer layer 80 is deposited over the buffer layer 64 after the buffer layer 64 has been patterned, such as shown in FIG. 12. The second buffer layer 80 may be deposited to a thickness in the range of about 3 μm to about 10 μm, though other thicknesses are possible. The second buffer layer 80 is then patterned using suitable techniques to expose the metal pads 50 and to expose the scribe regions 21. The sidewall characteristics of the second buffer layer 80 may be controlled by controlling the patterning process parameters, such as described previously for the buffer layer 64.

Referring to FIG. 19, a portion of a package 200 is shown, in accordance with some embodiments. The bottom edge of the second buffer layer 80 sidewall is indicated as point P3, and the top edge of the second buffer layer 80 sidewall is indicated as point P4. The buffer layer 64 shown in FIG. 19 is similar to that of the embodiment shown in FIG. 16. For example, the point P1 of the buffer layer 64 is laterally between the component edge 72 and the package edge 74 (e.g., is over the gap-filling material 32), and the point P2 of the buffer layer 64 is over the first package component 40. In FIG. 19, both points P3 and P4 of the second buffer layer 80 are over the first package component 40. The sidewall of the second buffer layer 80 may be recessed a distance D3 from the sidewall of the buffer layer 64. In some embodiments, a distance D3 between point P3 of the second buffer layer 80 and point P2 of the buffer layer 64 is in the range of about 0 μm to about 10 μm. Other distances are possible.

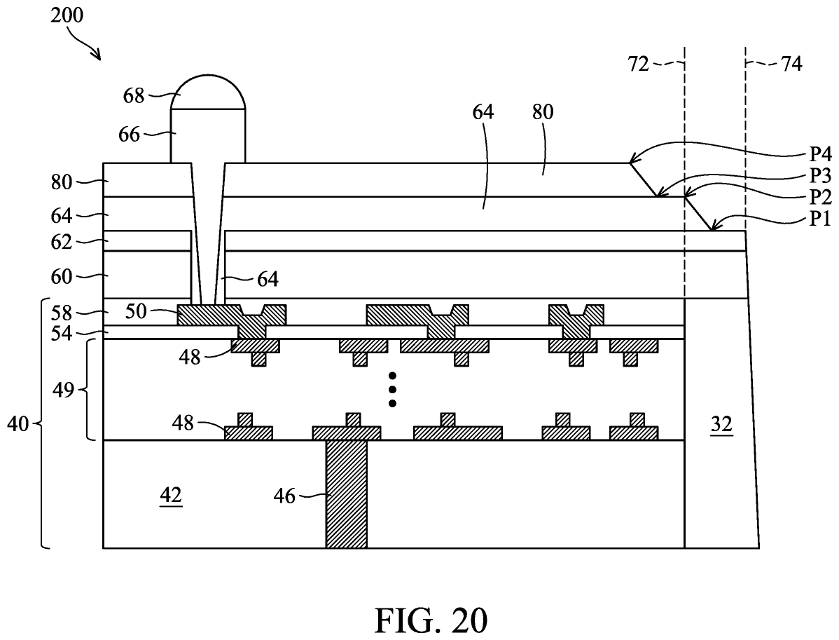

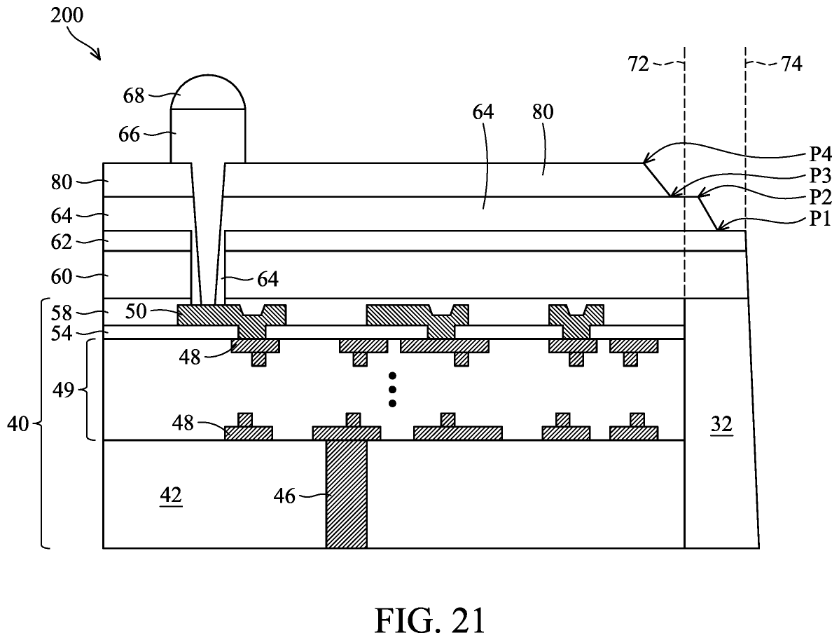

FIG. 20 illustrates a package 200 similar to that shown in FIG. 19, except that the buffer layer 64 is similar to that shown in FIG. 17. For example, the point P2 of the buffer layer 64 is approximately aligned with the component edge 72, and the point P1 of the buffer layer 64 is between the component edge 72 and the package edge 74. The points P3 and P4 of the second buffer layer 80 are over the first package component 40, similar to the package 200 of FIG. 19. FIG. 21 illustrates a package 200 similar to that shown in FIG. 19, except that the buffer layer 64 is similar to that shown in FIG. 18. For example, the points P1 and P2 of the buffer layer 64 are between the component edge 72 and the package edge 74 (e.g., are over the gap-filling material 32), and the points P3 and P4 of the second buffer layer 80 are over the first package component 40.

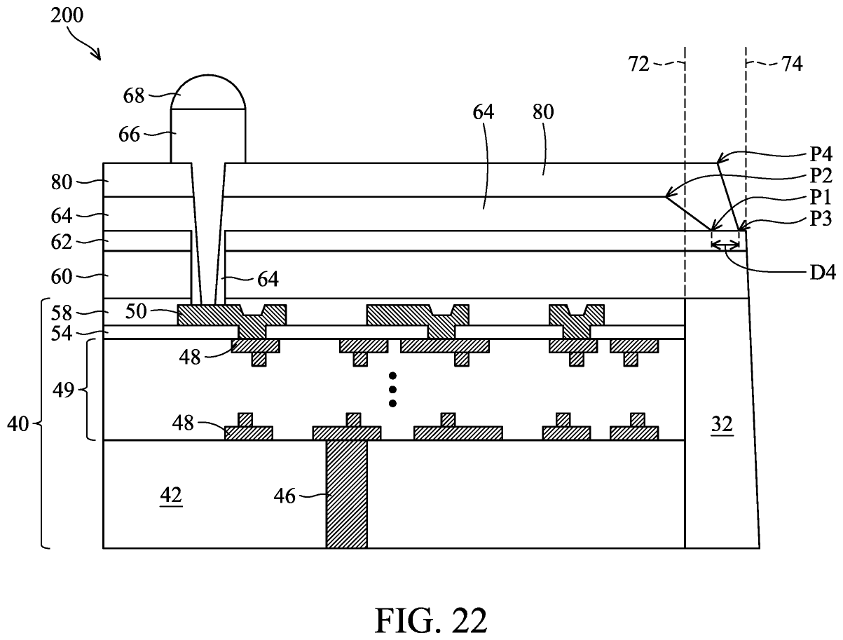

FIGS. 22 through 27 illustrate example packages 200 in which the second buffer layer 80 covers the buffer layer 64, in accordance with some embodiments. For example, a sidewall of the second buffer layer 80 is closer to the package edge 74 than a sidewall of the buffer layer 64. Referring to FIG. 22, a portion of a package 200 is shown, in accordance with some embodiments. The buffer layer 64 shown in FIG. 22 is similar to that of the embodiment shown in FIG. 16. For example, the point P1 of the buffer layer 64 is laterally between the component edge 72 and the package edge 74 (e.g., is over the gap-filling material 32), and the point P2 of the buffer layer 64 is over the first package component 40. In FIG. 22, both points P3 and P4 of the second buffer layer 80 are laterally between the component edge 72 and the package edge 74 (e.g., are over the gap-filling material 32). The sidewall of the buffer layer 64 may be recessed a distance D4 from the sidewall of the second buffer layer 80. In some embodiments, a distance D4 between point P3 of the second buffer layer 80 and point P1 of the buffer layer 64 is in the range of about 0 μm to about 10 μm. In some embodiments, the point P3 is a lateral distance from the package edge 74 that is in the range of about 0.1 μm to about 5 μm. Other distances are possible. The point P4 of the second buffer layer 80 may be approximately aligned with point P1 or may be laterally offset from point P1.

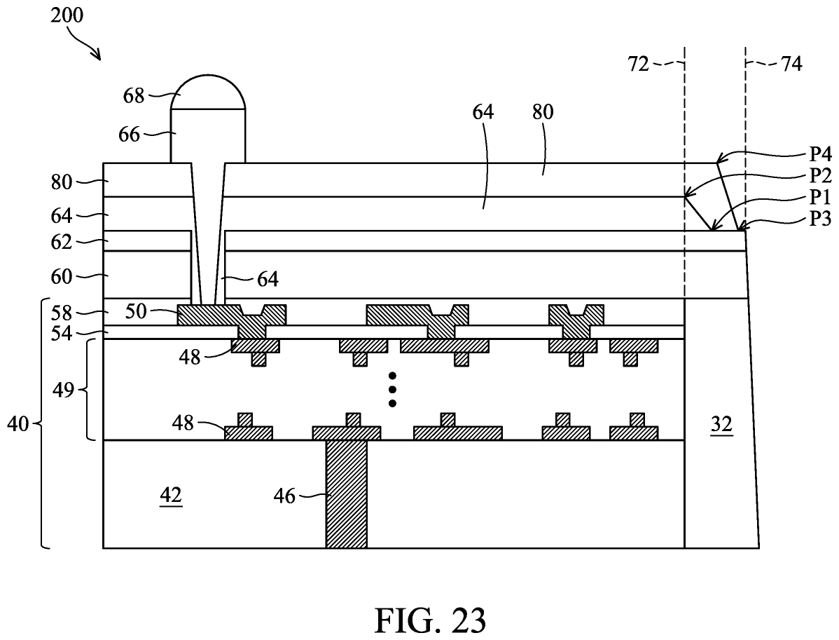

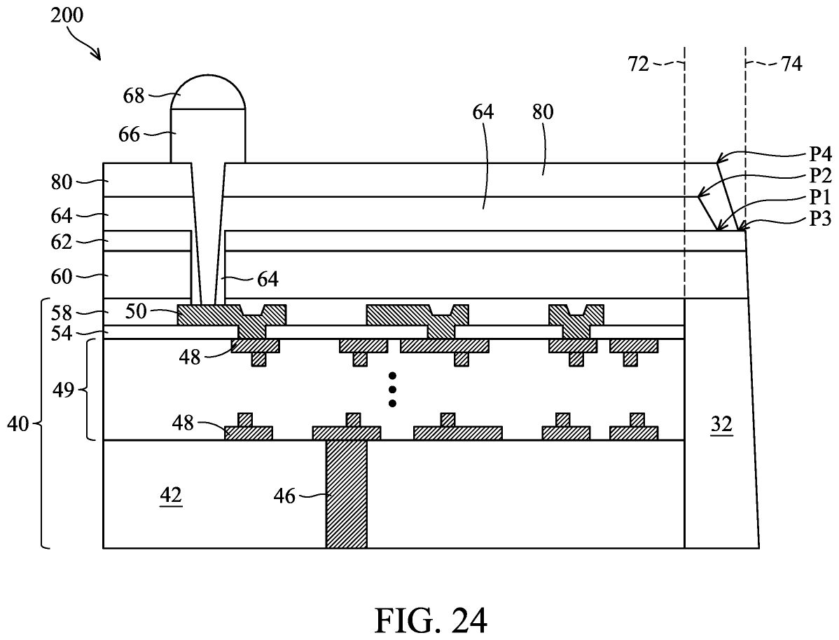

FIG. 23 illustrates a package 200 similar to that shown in FIG. 22, except that the buffer layer 64 is similar to that shown in FIG. 19. For example, the point P2 of the buffer layer 64 is approximately aligned with the component edge 72, and the point P1 of the buffer layer 64 is between the component edge 72 and the package edge 74. The points P3 and P4 of the second buffer layer 80 are laterally between the component edge 72 and the package edge 74 (e.g., are over the gap-filling material 32), similar to the package 200 of FIG. 22. FIG. 24 illustrates a package 200 similar to that shown in FIG. 19, except that the buffer layer 64 is similar to that shown in FIG. 21. For example, the points P1 and P2 of the buffer layer 64 and the points P3 and P4 of the second buffer layer 80 are between the component edge 72 and the package edge 74 (e.g., are over the gap-filling material 32). The point P4 of the second buffer layer 80 may be approximately aligned with point P1 or point P2, or may be laterally offset from point P1 and/or point P2.

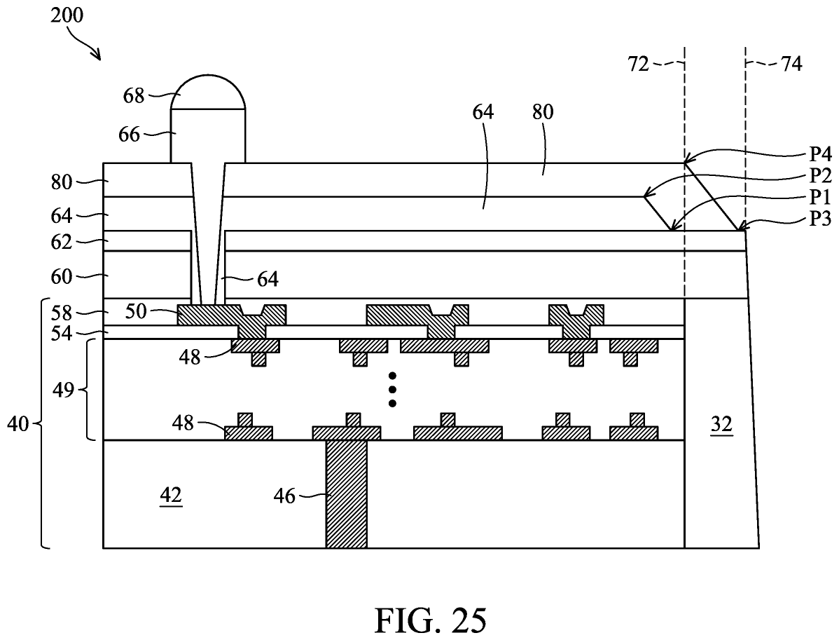

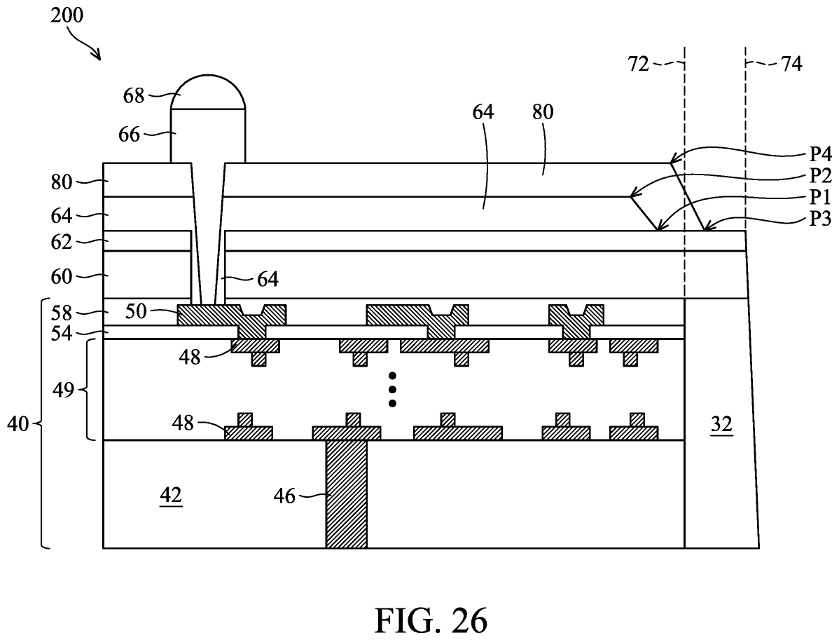

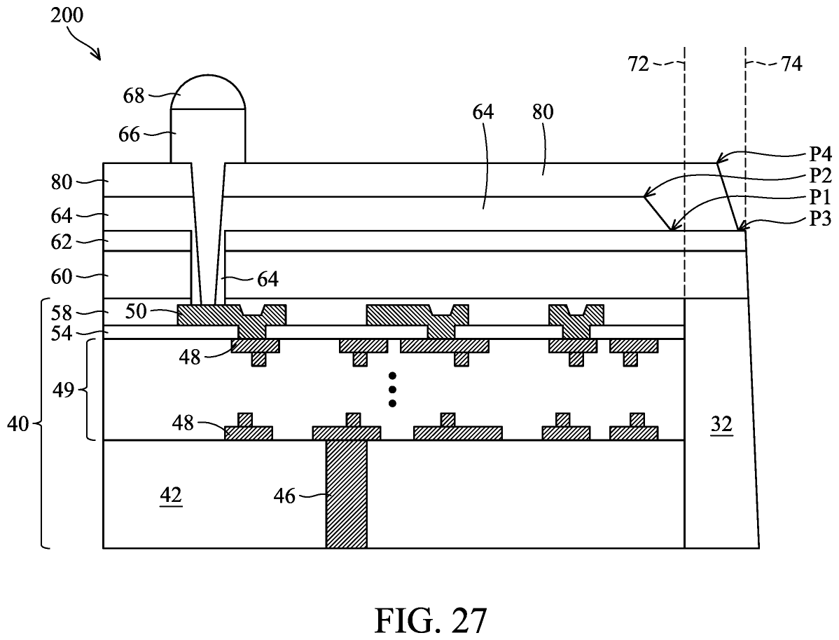

In FIGS. 25, 26, and 27, the points P1 and P2 of the buffer layer 64 are located over the first package component 40, in accordance with some embodiments. In other embodiments, the point P1 may be approximately aligned with the component edge 72. In FIG. 25, the point P3 of the second buffer layer 8o is between the component edge 72 and the package edge 74 (e.g., is over the gap-filling material 32), and the point P4 is approximately aligned with the component edge 72. In other embodiments, the point P4 may be laterally offset from the component edge 72. In FIG. 26, the point P3 is laterally between the component edge 72 and the package edge 74, and the point P4 is opposite the component edge 72 from the point P3. In other words, the point P3 is over the gap-filling material 32 and the point P4 is over the first package component 40. In FIG. 27, the points P3 and P4 of the second buffer layer 80 are between the component edge 72 and the package edge 74 (e.g., are over the gap-filling material 32).

The embodiments of the present disclosure have some advantageous features. A buffer layer is formed under conductive connectors of a semiconductor package, in which the semiconductor package comprises a package component surrounded by a gap-filling material. By having the buffer layer extend over the gap-filling material, stresses within the semiconductor package can be reduced. For example, in some cases, Coefficient of Thermal Expansion (CTE) mismatch between the buffer layer and the package component can cause warping, stress, peeling, or delamination. Extending the buffer layer past the edge of the package component as described herein can reduce the stresses due to CTE mismatch. The sidewall location and profile of the buffer layer can be controlled to minimize stress for a particular package design. Further, multiple buffer layers may be deposited, which can further reduce stress within the semiconductor package. In this manner, the thermal performance, yield, and reliability of a semiconductor package can be improved.

In an embodiment of the present disclosure, a device includes a package component including an interconnect structure on a first side of a substrate; metal pads on the interconnect structure; a semiconductor die connected to a second side of the substrate; a dielectric material surrounding the package component; a passivation layer extending over the package component and over the dielectric material; a first buffer layer over the passivation layer, wherein the first buffer layer extends over the package component and over the dielectric material, wherein a width of the first buffer layer is greater than a width of the package component and is less than a width of the passivation layer; and conductive connectors penetrating the passivation layer and the first buffer layer to physically contact the metal pads. In an embodiment, the first buffer layer physically contacts the metal pads. In an embodiment, top surfaces of the dielectric material and the package component are planar. In an embodiment, the first buffer layer includes one of polyimide, polybenzoxazole (PBO), or benzocyclobutene (BCB). In an embodiment, a portion of the first buffer layer over the dielectric material is sloped. In an embodiment, the device includes a second buffer layer on the first buffer layer, wherein the conductive connectors penetrates the second buffer layer. In an embodiment, the second buffer layer has a width that is greater than the width of the first buffer layer and that is less than the width of the passivation layer. In an embodiment, the second buffer layer has a width that is less than the width of the package component. In an embodiment, the first buffer layer has a thickness in the range of 3 μm to 10 μm.

In an embodiment of the present disclosure, a structure includes a first integrated circuit die including conductive pads; a gap-filling material covering a sidewall of the first integrated circuit die; a first polymer layer extending over top surfaces of the first integrated circuit die and the gap-filling material, wherein the first polymer layer physically contacts the conductive pads, wherein a sidewall of the first polymer layer is recessed from a sidewall of the gap-filling material; and conductive features extending through the first polymer layer to physically contact the conductive pads. In an embodiment, the sidewall of the first polymer layer is recessed from the sidewall of the gap-filling material by a distance in the range of 0.1 μm to 5 μm. In an embodiment, the sidewall of the first polymer layer is sloped at an angle that is less than 90°. In an embodiment, the structure includes a second polymer layer on the first polymer layer, wherein the conductive features extend through the second polymer layer. In an embodiment, a bottom edge of the sidewall of the first polymer layer is over the gap-filling material. In an embodiment, a top edge of the sidewall of the first polymer layer is over the first integrated circuit die. In an embodiment, a top edge of the sidewall of the first polymer layer is over the gap-filling material.

In an embodiment of the present disclosure, a method includes attaching a semiconductor die to a package component, wherein the package component includes metal pads; encapsulating the package component with an insulating material; depositing a passivation layer on surfaces of the package component and the insulating material; patterning the passivation layer to expose the metal pads; depositing a buffer layer over the patterned passivation layer; patterning the buffer layer to expose the metal pads and expose a surface of the passivation layer over the insulating material, wherein a portion of the patterned buffer layer extends from a metal pad to the exposed surface of the passivation layer; and forming conductive connectors on the metal pads. In an embodiment, the method includes performing a singulation process on the exposed surface of the passivation layer to remove portions of the passivation layer and the insulating material. In an embodiment, patterning the buffer layer includes exposing the buffer layer to light and developing the buffer layer. In an embodiment, a sloped surface of the buffer layer extends over a sidewall of the package component.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a package component comprising an interconnect structure on a first side of a substrate;
a plurality of metal pads on the interconnect structure;
a semiconductor die connected to a second side of the substrate;
a dielectric material surrounding the package component;
a passivation layer extending over the package component and over the dielectric material;
a first buffer layer over the passivation layer, wherein the first buffer layer extends over the package component and over the dielectric material, wherein a width of the first buffer layer is greater than a width of the package component and is less than a width of the passivation layer; and
a plurality of conductive connectors penetrating the passivation layer and the first buffer layer to physically contact the plurality of metal pads.

2. The device of claim 1, wherein the first buffer layer physically contacts the plurality of metal pads.

3. The device of claim 1, wherein top surfaces of the dielectric material and the package component are planar.

4. The device of claim 1, wherein the first buffer layer comprises one of polyimide, polybenzoxazole (PBO), or benzocyclobutene (BCB).

5. The device of claim 1, wherein a portion of the first buffer layer over the dielectric material is sloped.

6. The device of claim 1 further comprising a second buffer layer on the first buffer layer, wherein the plurality of conductive connectors penetrates the second buffer layer.

7. The device of claim 6, wherein the second buffer layer has a width that is greater than the width of the first buffer layer and that is less than the width of the passivation layer.

8. The device of claim 6, wherein the second buffer layer has a width that is less than the width of the package component.

9. The device of claim 1, wherein the first buffer layer has a thickness in the range of 3 μm to 10 μm.

10. A structure comprising:
a first integrated circuit die comprising a plurality of conductive pads;
a gap-filling material covering a sidewall of the first integrated circuit die;
a first polymer layer extending over top surfaces of the first integrated circuit die and the gap-filling material, wherein the first polymer layer physically contacts the plurality of conductive pads, wherein a sidewall of the first polymer layer is recessed from a sidewall of the gap-filling material; and
a plurality of conductive features extending through the first polymer layer to physically contact the plurality of conductive pads.

11. The structure of claim 10, wherein the sidewall of the first polymer layer is recessed from the sidewall of the gap-filling material by a distance in the range of 0.1 μm to 5 μm.

12. The structure of claim 10, wherein the sidewall of the first polymer layer is sloped at an angle that is less than 90°.

13. The structure of claim 10 further comprising a second polymer layer on the first polymer layer, wherein the plurality of conductive features extend through the second polymer layer.

14. The structure of claim 10, wherein a bottom edge of the sidewall of the first polymer layer is over the gap-filling material.

15. The structure of claim 10, wherein a top edge of the sidewall of the first polymer layer is over the first integrated circuit die.

16. The structure of claim 10, wherein a top edge of the sidewall of the first polymer layer is over the gap-filling material.

17. A method comprising:
attaching a semiconductor die to a package component, wherein the package component comprises metal pads;
encapsulating the package component with an insulating material;
depositing a passivation layer on surfaces of the package component and the insulating material;
patterning the passivation layer to expose the metal pads;
depositing a buffer layer over the patterned passivation layer;
patterning the buffer layer to expose the metal pads and expose a surface of the passivation layer over the insulating material, wherein a portion of the patterned buffer layer extends from a metal pad to the exposed surface of the passivation layer; and
forming conductive connectors on the metal pads.

18. The method of claim 17 further comprising performing a singulation process on the exposed surface of the passivation layer to remove portions of the passivation layer and the insulating material.

19. The method of claim 17, wherein patterning the buffer layer comprises:
exposing the buffer layer to light; and
developing the buffer layer.

20. The method of claim 17, wherein a sloped surface of the buffer layer extends over a sidewall of the package component.
